(19) United States
(12) Patent Application Publication
(10) Pub. No.: US 2026/0123415 A1
(43) Pub. Date: Apr. 30, 2026

(54) BALL GRID ARRAY PACKAGE

(71) Applicant: LG INNOTEK CO., LTD., Seoul (KR)

(72) Inventors: Chang Sung KIM, Seoul (KR); Tae Sup CHOI, Seoul (KR); Hyun Sung GUK, Seoul (KR)

(73) Assignee: LG INNOTEK CO., LTD., Seoul (KR)

(21) Appl. No.: 19/003,656

(22) Filed: Dec. 27, 2024

(30) Foreign Application Priority Data
Dec. 29, 2023 (KR) 10-2023-0196590

(51) Int. Cl. H01L 23/00; H01L 23/373; H01L 23/498

(52) U.S. Cl. CPC H10W 40/251; H10W 40/258; H10W 42/121; H10W 70/60; H10W 72/354; H10W 72/877; H10W 90/724; H10W 90/734; H10W 90/736

(57) ABSTRACT

The present embodiment relates to a ball grid array package. A ball grid array package according to one aspect includes: a substrate; an IC chip being disposed on the substrate; a ball electrically connecting the substrate and the IC chip; and a reinforcement part being disposed on the IC chip.

### TECHNICAL FIELD

The present embodiment relates to a ball grid array package

### BACKGROUND ART

The packaging process for semiconductor devices is performed after completing the manufacturing process of the semiconductor device, and the process sequence comprises the steps of: inspecting a wafer; mounting a wafer in which the wafer is attached onto an adhesive film; sawing in which a wafer made of multiple chips is cut to separate each chip; die bonding in which a die is attached to a lead frame on a package substrate using an adhesive material, the pad of the die and the lead of the package are wire bonded using a conductive metal wire, and the surroundings of the chip are coated with a protective material and bonded; and lead forming in which a lead is formed into a form that can be mounted on a PCB, and the package process is completed through the steps of marking, lead finishing, inspection, and testing.

In a ball grid array package, underfill is required to improve reliability of a ball against heat. During this process, if the underfill filler is not uniformly applied to the substrate surface, there is a risk of a short circuit between multiple balls due to a void phenomenon in an unfilled portion of the underfill of the substrate surface.

### PRIOR ART LITERATURE

### Patent Literature

(Patent Literature 1) Korean Patent Publication No. 10-1489469 (Published on Feb. 5, 2015)

### DETAILED DESCRIPTION OF THE INVENTION

### Technical Subject

The present invention is proposed to improve the above problems, and intended to provide a ball grid array package that can improve production efficiency by omitting underfill and prevent ball short.

### Technical Solution

The ball grid array package according to this embodiment comprises: a substrate; an IC chip being disposed on the substrate; a ball electrically connecting the substrate and the IC chip; and a reinforcement part being disposed on the IC chip.

### Advantageous Effects

Through the present embodiment, as the thermal expansion coefficient of the combined material is formed to be the same or similar to that of the substrate and the ball, and since the contraction and expansion of all components in the package are the same or similar according to temperature changes, there is an advantage of preventing cracks in the ball.

In addition, since the underfill process between the IC chip and the substrate can also be omitted, there is an advantage of improving production efficiency due to the reduction in assembly man-hours.

### BRIEF DESCRIPTION OF DRAWINGS

FIG. 1 is a cross-sectional view of a ball grid array package according to an embodiment of the present invention.

FIG. 2 is a diagram for explaining a change in physical properties due to the combining of a reinforcement part and an IC chip in a ball grid array package according to an embodiment of the present invention.

FIG. 3 is experimental data obtained by photographing the state of the ball through experiments in a ball grid array package according to an embodiment of the present invention and a ball grid array package according to a comparative example.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or arranged in “on (above)” or “below (under)” of each component, “on (above)” or “below (under)” means that it includes not only the case where the two components are directly in contact with, but also the case where one or more other components are formed or arranged between the two components. In addition, when expressed as “on (above)” or “below (under)”, the meaning of not only an upward direction but also a downward direction with respect to one component may be included.

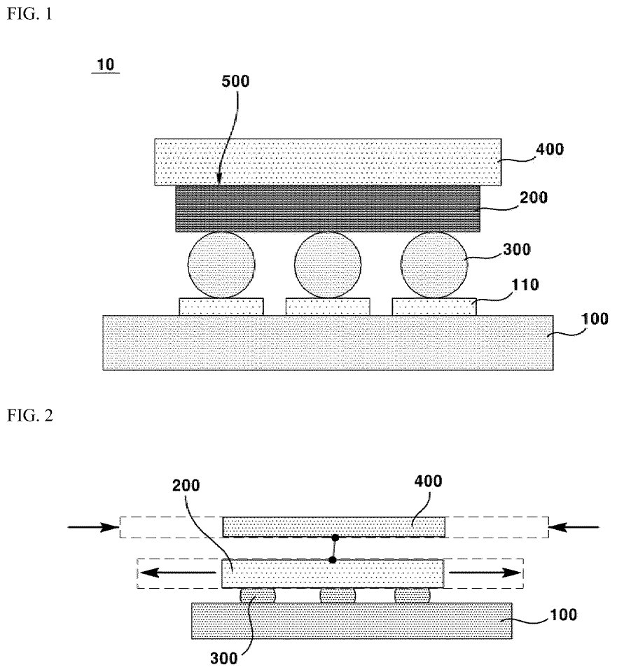

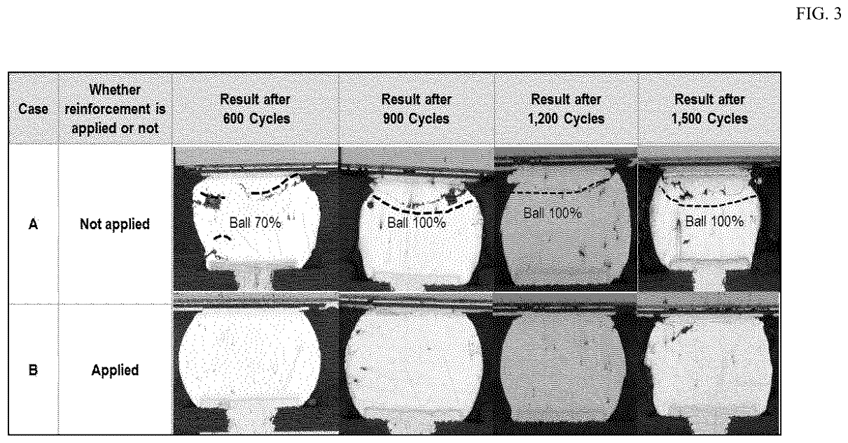

FIG. 1 is a cross-sectional view of a ball grid array package according to an embodiment of the present invention; FIG. 2 is a diagram for explaining a change in physical properties due to the combining of a reinforcement part and an IC chip in a ball grid array package according to an embodiment of the present invention; and FIG. 3 is experimental data obtained by photographing the state of the ball through experiments in a ball grid array package according to an embodiment of the present invention and a ball grid array package according to a comparative example.

Referring to FIGS. 1 and 2, a ball grid array package 10 according to an embodiment of the present invention may comprise a substrate 100, an IC chip 200, a ball 300, and a reinforcement part 400.

The substrate 100 may be formed in a plate shape. A circuit pattern 110 may be formed on a surface of the substrate 100 for electrical and physical combining with the ball 300. The circuit pattern 110 may be referred to as a terminal. The circuit patterns 110 may be provided in plural numbers and disposed to be spaced apart from one another on a surface of the substrate 100. The material of the circuit pattern 110 may be copper (Cu). The coefficient of thermal expansion (CTE) of the substrate 100 may be 17 ppm/° C. or more and 19 ppm/° C. or less. As an example, the thermal expansion coefficient of the substrate 100 may be 18 ppm/°C.

The IC chip 200 may be disposed on one surface of the substrate 100. The IC chip 200 may be disposed on an upper surface of the substrate 100. The IC chip 200 may be combined to an upper surface of the substrate 100. The IC chip 200 may be mounted on the substrate 100. The IC chip 200 may be mounted on the substrate 100 using a ball grid array (BGA) method.

The IC chip 200 may be made of resin or plastic.

The IC chip 200 may have a lower thermal expansion coefficient than that of the substrate 100. The thermal expansion coefficient of the IC chip 200 may be 4 ppm/° C. or more and 6 ppm/° C. or less. As an example, the thermal expansion coefficient of the IC chip 200 may be 5 ppm/° C.

The IC chip 200 may have a rectangular cross-sectional shape.

The ball 300 may be a solder ball. The ball 300 may have a circular or oval cross-sectional shape. The IC chip 200 and the substrate 100 can be electrically and physically combined through the ball 300. The ball 300 may be in contact with the metal area of the IC chip 200 and the circuit pattern 110 of the substrate 100, respectively. The ball 300 is melted through a reflow process to electrically connect the IC chip 200 and the substrate 100 between the IC chip 200 and the substrate 100.

The balls 300 may be provided in plural and disposed to be spaced apart from one another in a horizontal direction perpendicular to the vertical direction between the IC chip 200 and the substrate 100.

The thermal expansion coefficient of the ball 300 may be 19 ppm/° C. or more and 21 ppm/° C. or less. For example, the thermal expansion coefficient of the ball 300 may be 20 ppm/°C. The thermal expansion coefficient of the circuit pattern 110 may be the same as that of the ball 300.

The reinforcement part 400 may be disposed on an upper surface of the IC chip 200. The reinforcement part 400 may have a plate shape. The reinforcement part 400 may be made of metal. The reinforcement part 400 may be a metal plate. The materials of the reinforcement part 400 may include stainless steel (SUS) and aluminum (Al).

Unlike this, the material of the reinforcement part 400 may be a resin or a plastic. As an example, the material of the reinforcement part 400 may be an epoxy molding compound (EMC).

The cross-sectional area of the reinforcement part 400 may be larger than the cross-sectional area of the IC chip 200. The thickness of the reinforcement part 400 may be greater than the thickness of the IC chip 200. Unlike this, the thickness of the reinforcement part 400 may be thinner than the thickness of the IC chip 200. The thickness of the reinforcement part 400 may be 0.2 mm or more and 0.6 mm or less. When the thickness of the reinforcement part 400 exceeds 0.6 mm, there is a problem in that the combining strength with the IC chip 200 is reduced. When the thickness of the reinforcement part 400 is less than 0.2 mm, the physical properties may not change due to the combining with the IC chip 200, which will be described later.

The reinforcement part 400 may be combined with the IC chip 200 using an adhesive 500. The adhesive 500 may include epoxy. The adhesive 500 can be applied to at least one of a lower surface of the reinforcement part 400 or an upper surface of the IC chip 200 to combine the reinforcement part 400 and the IC chip 200 to each other.

The thermal expansion coefficient of the reinforcement part 400 may be greater than that of the IC chip 200. When the combined configuration of the reinforcement part 400 and the IC chip 200 is referred to as a combined object, the thermal expansion coefficient of the combined object is greater than that of the IC chip 200, and the thermal expansion of the reinforcement part 400 may be smaller than the coefficient.

The thermal expansion coefficient of the combined object may be 10 ppm/° C. or more and 20 ppm/° C. or less.

The difference between the thermal expansion coefficient of the combined object and the thermal expansion coefficient of the substrate 100 or the difference between the thermal expansion coefficient of the combined object and the thermal expansion coefficient of the ball 300 may be 10 ppm/° C. or less.

When the reinforcement part 400, which has a relatively high thermal expansion coefficient, is combined on the IC chip 200, the low thermal expansion coefficient of the IC chip 200 can be compensated for through the combined object. That is, as illustrated in FIG. 2, even if tensile stress is generated in the IC chip 200 due to heat generation during the reflow process, compressive stress may be generated in the reinforcement part 400 having a high thermal expansion coefficient under the temperature conditions of the reflow process.

That is, as the ball grid array package 10 according to the present embodiment forms the thermal expansion coefficient of the combined object to be the same or similar to the thermal expansion coefficient of the substrate 100 and the ball 300, and since the contraction and expansion of all components in the package according to temperature changes are the same or similar, there is an advantage of preventing cracks in the ball 300. Accordingly, the underfill process between the IC chip 200 and the substrate 100 can also be omitted, so there is an advantage of improving production efficiency due to the reduction in assembly man-hours.

Referring to FIG. 3, it can be confirmed that cracks occur under various conditions due to thermal shock in the case of a ball in a comparative example to which the reinforcement part 400 is not applied, but it can be confirmed that the ball grid array package 10 according to the present embodiment to which the reinforcement part 400 is applied does not generate cracks under various conditions of thermal shock.

In the above description, it is described that all the components constituting the embodiments of the present invention are combined or operated in one, but the present invention is not necessarily limited to these embodiments. In other words, within the scope of the present invention, all of the components may be selectively operated in combination with one or more. In addition, the terms “comprise”, “include” or “having” described above mean that the corresponding component may be inherent unless specifically stated otherwise, and thus it should be construed that it does not exclude other components, but further include other components instead. All terms, including technical and scientific terms, have the same meaning as commonly understood by one of ordinary skill in the art unless otherwise defined. Terms used generally, such as terms defined in a dictionary, should be interpreted to coincide with the contextual meaning of the related art, and shall not be interpreted in an ideal or excessively formal sense unless explicitly defined in the present invention.

The above description is merely illustrative of the technical idea of the present invention, and those skilled in the art to which the present invention pertains may make various modifications and changes without departing from the essential characteristics of the present invention. Therefore, the embodiments disclosed in the present invention are not intended to limit the technical idea of the present invention but to describe the present invention, and the scope of the technical idea of the present invention is not limited by these embodiments. The protection scope of the present invention should be interpreted by the following claims, and all technical ideas within the equivalent scope should be interpreted as being included in the scope of the present invention.

1. A ball grid array package comprising:
a substrate;
an IC chip disposed on the substrate;
a ball electrically connecting the substrate; and
a reinforcement part disposed on the IC chip.

2. The ball grid array package according to claim 1,
wherein the reinforcement part is a metal plate.

3. The ball grid array package according to claim 1,
wherein the material of the reinforcement part is a resin or a plastic.

4. The ball grid array package according to claim 1,
wherein a thermal expansion coefficient of the reinforcement part is greater than that of the IC chip.

5. The ball grid array package according to claim 1,
wherein a combined object is formed by a combining of the IC chip and the reinforcement part, and
wherein a difference between a thermal expansion coefficient of the combined object and a thermal expansion coefficient of the substrate or a difference between the thermal expansion coefficient of the combined object and a thermal expansion coefficient of the ball is 10 ppm/° C. or less.

6. The ball grid array package according to claim 1, including:
an adhesive combining the IC chip and the reinforcement part.

7. The ball grid array package according to claim 6,
wherein the adhesive includes an epoxy.

8. The ball grid array package according to claim 1,
wherein a cross-sectional area of the reinforcement part is larger than a cross-sectional area of the IC chip.

9. The ball grid array package according to claim 1,
wherein a thickness of the reinforcement part is greater than a thickness of the IC chip.

10. The ball grid array package according to claim 1, including:
a circuit pattern formed on a surface of the substrate to be combined with the ball,
wherein a thermal expansion coefficient of the circuit pattern is equal to a thermal expansion coefficient of the ball.

11. The ball grid array package according to claim 1, wherein a thickness of the reinforcement part is 0.2 mm or more and 0.6 mm or less.

12. The ball grid array package according to claim 1, wherein a thickness of the reinforcement part is smaller than a thickness of the IC chip.

13. The ball grid array package according to claim 2, wherein a material of the reinforcement part includes stainless steel (SUS) or aluminum (Al).

14. The ball grid array package according to claim 3, wherein a material of the reinforcement part is EMC (Epoxy Molding Compound).

15. The ball grid array package according to claim 1, wherein the thermal expansion coefficient of the IC chip is 4 ppm/° C. or more and 6 ppm/° C. or less, and
wherein a thermal expansion coefficient of the substrate is 17 ppm/° C. or more and 19 ppm/° C. or less.

16. A ball grid array package comprising:
a substrate;
an IC chip disposed on the substrate;
a ball electrically connecting the substrate; and
a reinforcement part disposed on the IC chip,
wherein materials of the reinforcement part and the IC chip are different from each other, and
wherein a thermal expansion coefficient of the reinforcement part is greater than that of the IC chip.

17. The ball grid array package according to claim 16,
wherein the reinforcement part is a metal plate.

18. The ball grid array package according to claim 16,
wherein the material of the reinforcement part is a resin or a plastic.

19. The ball grid array package according to claim 16,
wherein a combined object is formed by a combining of the IC chip and the reinforcement part, and
wherein a difference between a thermal expansion coefficient of the combined object and a thermal expansion coefficient of the substrate or a difference between the thermal expansion coefficient of the combined object and a thermal expansion coefficient of the ball is 10 ppm/° C. or less.

20. The ball grid array package according to claim 16,
wherein a thickness of the reinforcement part is greater than a thickness of the IC chip.
